(19) United States
(12) Patent Application Publication
(10) Pub. No.: US 2010/0169742 A1
(43) Pub. Date: Jul. 1, 2010

(54) FLASH MEMORY SOFT ERROR RECOVERY

(75) Inventor: Harland Glenn Hopkins, Missouri City, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/345,557

(22) Filed: Dec. 29, 2008

(51) Int. Cl. H03M 13/05; G06F 11/07

(52) U.S. Cl. 714/764; 714/E11.021

(57) ABSTRACT

In an embodiment, the invention provides a method for correcting soft errors in memory. A block of data is written in memory wherein all rows and all columns have a first checksum appended to it. A second checksum for each row and each column is generated after reading each row and each column from memory. The first and second checksum for each row and each column are compared for a compare such that when one and only one column has a miscompare, the logical value of any bit at an intersection of the one and only one column that has a miscompare and any row that has a miscompare is reversed.

### BACKGROUND

Soft errors may occur in integrated circuits (ICs) when radioactive atoms decay and release alpha particles into an IC. Because an alpha particle contains a positive charge and kinetic energy, the alpha particle can hit a memory cell and cause the cell to change from one logical state to another. For example, when an alpha particle strikes a memory cell, the strike may cause the memory cell to change or “flip” from a logical “zero” to a logical “one.” Usually the alpha particle strike does not damage the actual structure of an IC.

A common source of soft errors are alpha particles which may be emitted by trace amounts of radioactive isotopes present in packing materials of integrated circuits. “Bump” material used in flip-chip packaging techniques has also been identified as a possible source of alpha particles.

Other sources of soft errors include high-energy cosmic rays and solar particles. High-energy cosmic rays and solar particles react with the upper atmosphere generating high-energy protons and neutrons that shower to the earth. Neutrons can be particularly troublesome as they can penetrate most man-made construction (a neutron can easily pass through five feet of concrete). This effect varies with both latitude and altitude. In London, the effect is two times worse than on the equator. In Denver, Colo. with its mile-high altitude, the effect is three times worse than at sea-level San Francisco. In a commercial airplane, the effect can be 100-800 times worse than at sea-level.

Soft errors may also be caused by manufacturing defects. For example, if a defect causes enough leakage on a floating gate of a flash memory cell, the flash memory cell may flip.

Soft errors are becoming one of the main contributors to failure rates in microprocessors and other complex ICs. Several approaches have been suggested to reduce this type of failure. Adding ECC (Error Correction Code) or parity in blocks of memory may reduce this type of failure. Adding ECC can be complex and add to the cost of producing an IC.

### BRIEF DESCRIPTION OF THE DRAWINGS

FIG. 1 is a schematic diagram of a side cutaway view of an embodiment of a flash memory cell.

FIG. 2A is a block diagram of an exemplary embodiment of a method for writing data with checksums to memory.

FIG. 2B is a block diagram of an exemplary embodiment of a method for correcting soft errors in memory.

FIG. 3 is a flow diagram illustrating an embodiment of a method for correcting soft errors in memory.

FIG. 4A is a schematic drawing illustrating an embodiment of a method for correcting a single soft error in memory.

FIG. 4B is a schematic drawing illustrating an embodiment of a method for correcting more than one soft error in memory.

FIG. 4C is a schematic drawing illustrating an embodiment of a method for correcting all soft errors in a column of memory where all bits in the column contain soft errors.

### DETAILED DESCRIPTION

In an embodiment of the invention, soft errors may be corrected in a block of memory based on row and column CRC checksum computations. This is explained in more detail below.

Flash memory stores information in an array of memory cells made from floating-gate transistors. In traditional single-level cell (SLC) devices, each cell stores only one bit of information. Some flash memory, known as multi-level cell (MLC) devices, can store more than one bit per cell by choosing between multiple levels of electrical charge to apply to the floating gates of its cells.

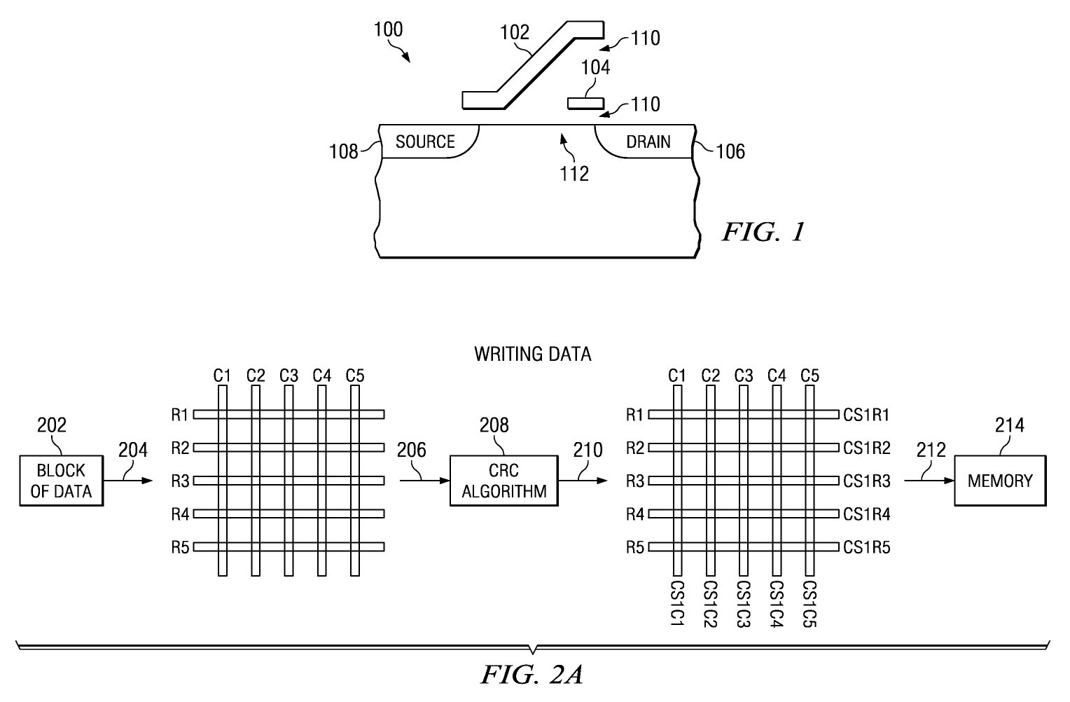

FIG. 1 is a schematic diagram of a side cutaway view of an embodiment of a flash memory cell. In NOR-gate flash memory, each flash memory cell (100) resembles a standard MOSFET (metal-oxide semiconductor field-effect transistor) except the transistor has two gates instead of one. On top is the control gate (102), as in other MOS (metal-oxide semiconductor) transistors, however below the control gate (102) there is a floating gate (104) insulated by an oxide layer (110). The floating gate (104) is interposed between the control gate (102) and the MOSFET channel (112).

Because the floating gate (104) is electrically isolated by the oxide layer (110), any electrons placed on the floating gate (104) are trapped on the floating gate (104). Under normal conditions, the floating gate (104) will not discharge for many years. When the floating gate (104) retains charge, it screens (partially cancels) the electric field from the control gate (102), which modifies the V_{T} (threshold voltage) of the cell. During read-out, a voltage is applied to the control gate (102), and the MOSFET channel (112) will become conducting or remain insulating, depending on the V_{T} of the cell, which is in turn controlled by charge on the floating gate (104).

If the MOSFET channel (112) becomes conducting, current flows through the MOSFET channel (112) from the drain (106) to the source (108). The absence or the presence of current flowing through the MOSFET channel (112) may be sensed forming a binary code wherein stored data may be reproduced.

In a multi-level cell device, which stores more than one bit per cell, the amount of current flow is sensed (rather than simply its presence or absence), in order to determine more precisely the level of charge on the floating gate (104).

Flash memory is primarily used in memory cards and USB flash drives for general storage and transfer of data between computers and other digital products. Flash memory is erased and programmed in large blocks. Because large blocks of memory are subject to soft errors, error correction and error detection techniques are often used to correct and/or detect soft errors in memory.

An Error Correcting Code (ECC) is a code in which data being transmitted or written conforms to specific rules of construction so that departures from this construction in the received or read data may be detected and/or corrected. Some codes can detect a certain number of bit errors and correct a smaller number of bit errors. Codes which can correct one error are termed single error correcting (SEC), and those which detect two are termed double error detecting (DED). A Hamming code, for example, may correct single-bit errors and detect double-bit errors (SEC-DED). More sophisticated codes correct and detect even more errors. Examples of error correction code include Hamming code, Reed-Solomon code, Reed-Muller code and Binary Golay code.

Memory systems that use ECC may have disadvantages over memory systems that do not use ECC. For example, memory systems using ECC may require more physical memory than a memory system that does not use ECC. Typically, 64 bytes (a byte contains 8 bits of data) of memory requires an extra 1 byte of memory in order to implement ECC. This represents an increase in physical memory of 12.5 percent. When implemented at a system level, for example, ECC may require 9 memory ICs (integrated circuits) whereas a system that does not use ECC would only require 8 memory ICs. With this amount of extra memory, ECC may correct a single error and detect a double error.

A cyclic redundancy check (CRC), is a technique for detecting errors in digital data, but not for making corrections when errors are detected. In the CRC method, a certain number of check bits, often called a checksum, are appended to the data being transmitted or written.

For example, one method of creating a CRC algorithm is to treat the data transmitted or written as a binary number, to divide it by another fixed binary number, and to make the remainder from this division the checksum. For example, after receiving the sent data, a receiver can perform the same division and compare the remainder with the checksum (sent remainder). If the remainder is identical to the checksum, the data transmitted or written usually does not have an error. However, if the remainder and the checksum are not identical, an error has occurred in the data transmitted or written. Other algorithms may be used to create checksums. For example, a “hash” function or polynomial arithmetic may be used to produce a checksum.

Typically CRC does not require as much redundancy as ECC. For example, a 262,144 byte flash memory may only require 3,072 bytes of extra memory to implement CRC. In this example, a row contains 2,048 bits of data. Only 1 byte of extra memory per row of memory is needed for CRC. In this example, a column contains 1024 bits of data. Only 1 byte of extra memory per column is needed for CRC. As result, only 1.2 percent extra memory is needed to implement CRC. ECC with double error detect and single error correct requires 12.5 percent extra memory as indicated above.

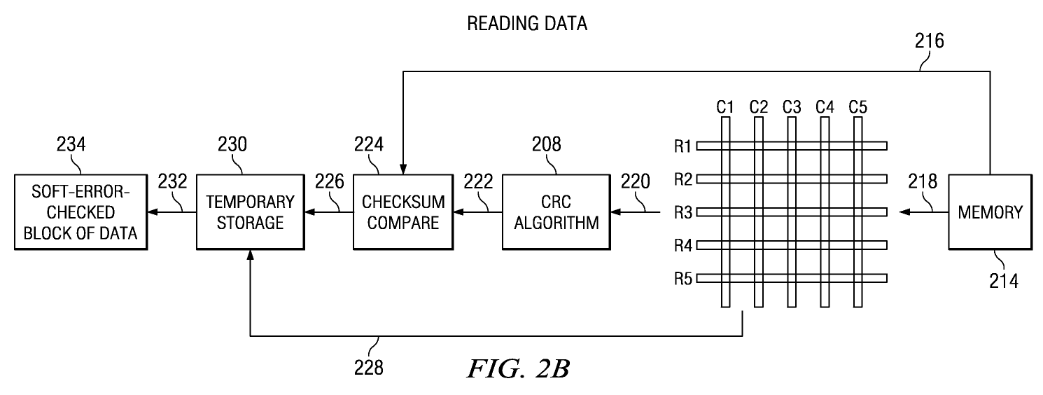

FIG. 2A is a block diagram of an exemplary embodiment of a method for writing data with checksums to memory. A block of data 202 may be divided into rows and columns. For example as shown in FIG. 2A, a block of data 202 may be divided in to five rows (R1-R5) and five columns (C1-C5). In this example, each row (R1-R5) is separately operated on by a CRC algorithm 208. For each individual row (R1-R5) operated on by the CRC algorithm 208, a first checksum (CS1R1-CS1R5) is created. In this example, each column (C1-C5) is separately operated on by the CRC algorithm 208. For each individual column (C1-C5) operated on by the CRC algorithm 208, a first checksum (CS1C1-CS1C5) is created.

Each first checksum created for each row (R1-R5) and each column (C1-C5) is then appended to the individual row or column that was used to create the first checksum. In this example, row R1 has a first checksum CS1R1 appended to it and column C1 has a first checksum CS1C1 appended to it. In this example, after all rows (R1-R5) and all columns (C1-C5) have had their respective first checksums (CS1R1-CS1R5 and CS1C1-CS1C5) appended, all rows (R1-R5) and columns (C1-C5) with their respective appended first checksums (CS1R1-CS1R5 and CS1C1-CS1C5) are written to memory 214.

FIG. 2B is a block diagram of an exemplary embodiment of a method for correcting soft errors in memory. After all rows (R1-R5) and columns (C1-C5) with their respective appended first checksums (CS1R1-CS1R5 and CS1C1-CS1C5) are written to memory 214, they may be read from the memory 214. When all rows (R1-R5) and columns (C1-C5) with their respective appended first checksums (CS1R1-CS1R5 and CS1C1-CS1C5) have been read from memory 214, all first checksums (CS1R1-CS1R5 and CS1C1-CS1C5) are sent via connection 216 to a checksum compare block 224.

In this example, each row (R1-R5), without its appended first checksum (CS1R1-CS1R5) is separately operated on by the CRC algorithm 208. For each individual row (R1-R5) operated on by the CRC algorithm 208, a second checksum (CS2R1-CS2R5) is created. Each second checksum (CS2R1-CS2R5) is then sent via connection 222 to the checksum compare block 224.

In this example, each column (C1-C5), without its appended first checksum (CS1C1-CS1R5) is separately operated on by the CRC algorithm 208. For each individual column (C1-C5) operated on by the CRC algorithm 208, a second checksum (CS2C1-CS2C5) is created. Each second checksum (CS2C1-CS2C5) is then sent via connection 222 to the checksum compare block 224.

Rows (R1-R5) and columns (C1-C5) are stored via connection 228 in temporary storage block 230.

After all first checksums (CS1R1-CS1R5 and CS1C1-CS1C5) and all second checksums (CS2R1-CS2R5 and CS2C1-CS2C5) are sent to the checksum compare block 224, each first checksum is compared to each second checksum respectively. For example, CS1R1 is compared to CS2R1, CS1R5 is compared to CS2R5, and CS1C2 is compared to CS2C2 etc. until all checksums have been compared.

When two checksums are compared and they are identical, a “compare” is created for the row or column from which the checksums were created. If all the rows (R1-R5) and all the columns (C1-C5) compare, no soft errors were found in the rows and columns. If no soft errors are found in the rows and columns, the data in the temporary storage block 230 is sent via connection 232 to the Soft-Error-Checked Block of Data 234.

After all checksums have been compared and one and only one column from the plurality of all columns (in this example columns C1-C5) has a “miscompare,” any and all bits that were flipped in the one and only one column due to soft errors, may be corrected to the original stored logical value.

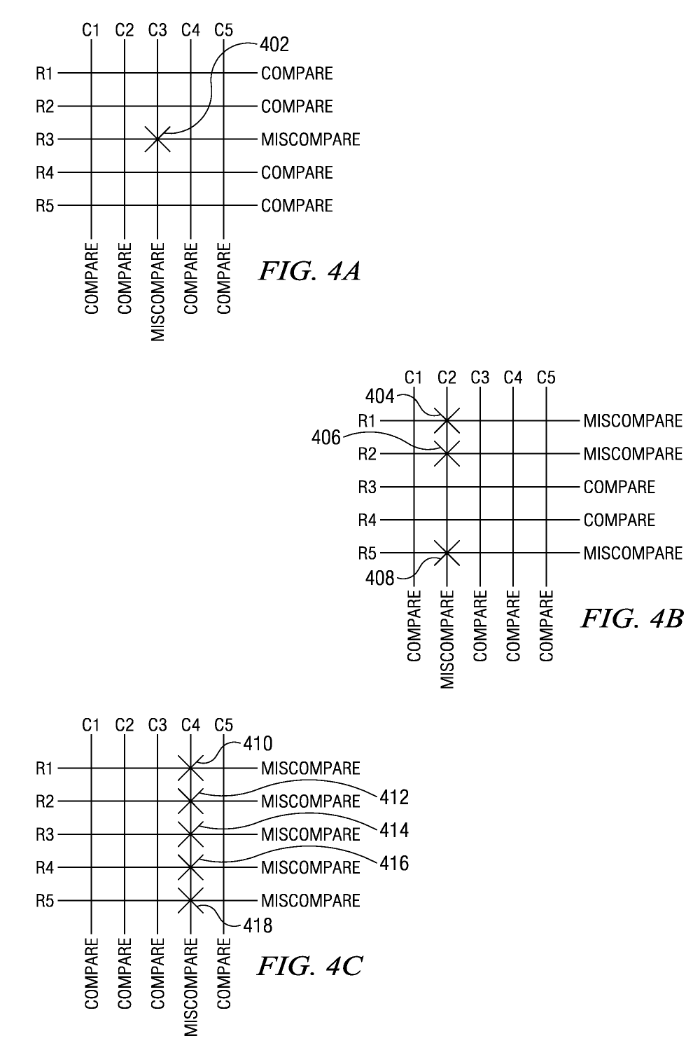

FIG. 4A is a schematic drawing illustrating an embodiment of a method for correcting a single soft error in memory. In the example shown in FIG. 4A, only column C3 from the plurality of all columns (C1-C5) has a miscompare. Because one and only one column, C3, from the plurality of all columns (C1-C5) has a miscompare, a soft error may be corrected. In this example, row R3 has a miscompare. Because row R3 and column C3 have a miscompare, the bit 402 at the intersection of row R3 and column C3 was flipped. In this example, bit 402 may be corrected.

Bit 402 in this example is corrected when checksum compare 224 changes the flipped bit 402 in temporary storage 230 via connection 226. After bit 402 is corrected, all the data in the temporary storage 230 is transferred via connection 232 to the Soft-Error-Checked block of data 234.

FIG. 4B is a schematic drawing illustrating an embodiment of a method for correcting more than one soft error in memory. In the example shown in FIG. 4B, only column C2 from the plurality of all columns (C1-C5) has a miscompare. Because one and only one column, C2, from the plurality of all columns (C1-C5) has a miscompare, any soft error in the column C2 may be corrected. In this example, rows R1, R2 and R5 have miscompares. Because rows R1, R2, R5 and column C2 have miscompares, the bits 404, 406 and 408 were flipped. In this example, bits 404, 406 and 408 may be corrected.

Bits 404, 406 and 408 in this example are corrected when checksum compare 224 changes the flipped bits 404, 406 and 408 in temporary storage 230 via connection 226. After bits 404, 406 and 408 are corrected, all the data in the temporary storage 230 is transferred via connection 232 to the Soft-Error-Checked block of data 234.

FIG. 4C is a schematic drawing illustrating an embodiment of a method for correcting all soft errors in a column of memory where all bits in the column contain soft errors. In the example shown in FIG. 4C, only column C4 from the plurality of all columns (C1-C5) has a miscompare. Because one and only one column, C4, from the plurality of all columns (C1-C5) has a miscompare, any soft error in the column C4 may be corrected. In this example, rows R1-R5 have miscompares. Because rows R1-R5 and column C4 have miscompares, the bits 410, 412, 414, 416 and 418 were flipped. In this example, bits 410, 412, 414, 416 and 418 may be corrected.

Bits 410, 412, 414, 416 and 418 in this example are corrected when checksum compare 224 changes the flipped bits 410, 412, 414, 416 and 418 in temporary storage 230 via connection 226. After bits 410, 412, 414, 416 and 418 are corrected, all the data in temporary storage 230 is transferred via connection 232 to the Soft-Error-Checked block of data 234.

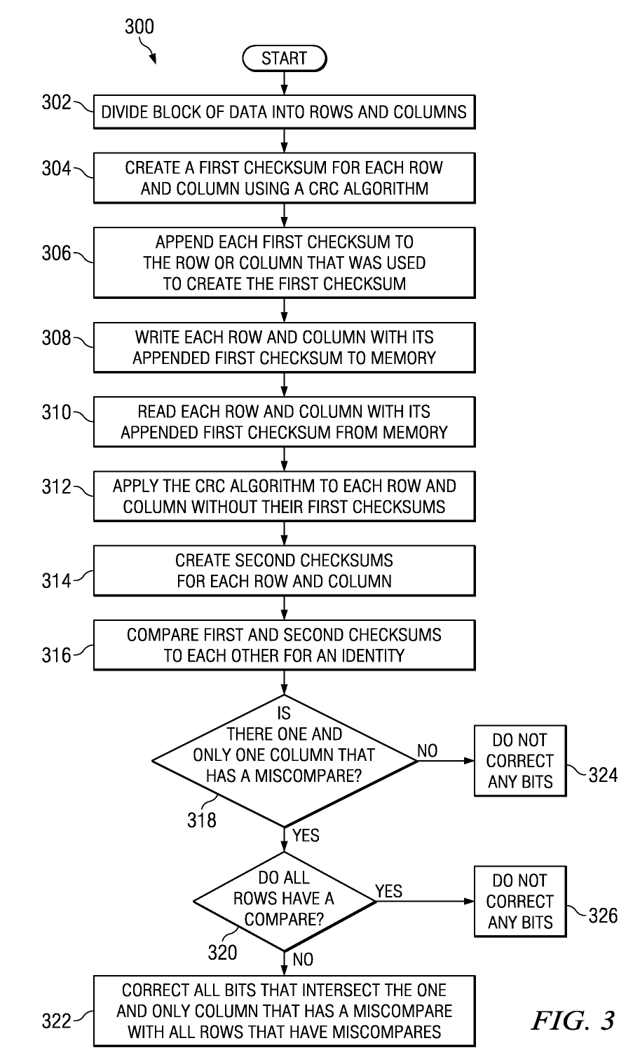

FIG. 3 is a flow diagram illustrating an embodiment of a method for correcting soft errors in memory. In FIG. 3, box 302 indicates that a block of data is divided into rows and columns. In box 304, a first checksum is created for each row and column using a CRC algorithm. Next, in box 306, the first checksum for each row and column is appended to the respective row or column that created the first checksum. Box 308 indicates that each row and each column with its appended checksum is written to memory.

After each row and each column with its appended checksum is written to memory, box 310 indicates each row and each column with its appended checksum is read from memory. Box 312 indicates that each row and each column without their first checksums is applied to the CRC algorithm. Next box 314 indicates that a second checksum for each row and each column is created. Box 316 indicates that the first and second checksum for each row and each column are compared. If the first and second checksum are identical for a specific row or column, that specific row or column has a compare.

The diamond 318 verifies whether or not one and only one column has a miscompare. If there is more than one column that has a miscompare or no columns have a miscompare, no bits will be corrected as indicated in box 324. If there is one and only one column that has a miscompare, diamond 320 verifies whether all rows have compares. If all rows have compares, no bits will be corrected as indicated in box 326. If one or more rows have a miscompare, correct all the bits that intersect the one and only one column that has a miscompare and the one or more rows that have miscompares as shown in box 322.

The foregoing description has been presented for purposes of illustration and description. It is not intended to be exhaustive or to limit the invention to the precise form disclosed, and other modifications and variations may be possible in light of the above teachings. The exemplary embodiments were chosen and described in order to best explain the applicable principles and their practical application to thereby enable others skilled in the art to best utilize various embodiments and various modifications as are suited to the particular use contemplated. It is intended that the appended claims be construed to include other alternative embodiments except insofar as limited by the prior art.

What is claimed is:

1. A method for correcting soft errors in memory, the method comprising:
writing a block of data into the memory wherein the block of data comprises a plurality of rows and a plurality of columns, wherein each row in the plurality of rows and each column in the plurality of columns has a first checksum appended to it;
generating a second checksum for each row in the plurality of rows and each column in the plurality of columns when each row and each column is read from the memory;
comparing each first checksum to its corresponding second checksum for each row in the plurality of rows for a compare;
comparing each first checksum to its corresponding second checksum for each column in the plurality of columns for a compare;
wherein when one and only one column has a miscompare, a logical value of any bit at an intersection of the one and only one column that has a miscompare and any row that has a miscompare is reversed.

2. The method as in claim 1 wherein writing a block of data into the memory comprises:
creating the first checksum for each row in the plurality of rows and for each column in the plurality of columns using a CRC algorithm;
appending the first checksum created for each row in the plurality of rows to a row that created the first checksum;
appending the first checksum created for each column in the plurality of columns to the column that created the first checksum;
writing each row in the plurality of rows with its appended first checksum to the memory;
writing each column in the plurality of columns with its appended first checksum to the memory.

3. The method as in claim 1 wherein generating a second checksum for each row in the plurality of rows and each column in the plurality of columns comprises:
reading each row in the plurality of rows with its appended first checksum from the memory;
reading each column in the plurality of columns with its appended first checksum from the memory;
applying the CRC algorithm to each row read from the plurality of rows without its appended first checksum wherein a second checksum is created for each row from the plurality of rows;
applying the CRC algorithm to each column read from the plurality of columns without its appended first checksum wherein a second checksum is created for each column from the plurality of columns.

4. The method as in claim 1 wherein the memory is a flash memory.

5. The method as in claim 1 wherein the memory is a magnetic memory.

6. The method of claim 1 wherein the memory is a DRAM memory.

7. The method of claim 1 where the memory is an SRAM memory.

8. The method as in claim 3 wherein the CRC algorithm is a hash function.

9. The method as in claim 3 wherein the CRC algorithm uses polynomial arithmetic.

10. The method as in claim 1 where the block of data contains 262,144 bytes of data.

11. The method of claim 10 wherein a row contains 2,048 bits of data and a column contains 1,024 bits of data.

12. The method of claim 11 wherein the checksum for each row and column contains 1 byte of data.

13. An apparatus for correcting soft errors in memory, the apparatus comprising:
at least one computer readable medium; and
a computer readable program code stored on said at least one computer readable medium, said computer readable program code comprising instructions for:
writing a block of data into the memory wherein the block of data comprises a plurality of rows and a plurality of columns, wherein each row in the plurality of rows and each column in the plurality of columns has a first checksum appended to it;
generating a second checksum for each row in the plurality of rows and each column in the plurality of columns when each row and each column is read from the memory;
comparing each first checksum to its corresponding second checksum for each row in the plurality of rows for a compare;
comparing each first checksum to its corresponding second checksum for each column in the plurality of columns for a compare;
wherein when one and only one column has a miscompare, a logical value of any bit at an intersection of the one and only one column that has a miscompare and any row that has a miscompare is reversed.

14. The apparatus as in claim 13 wherein writing a block of data into the memory comprises:
creating the first checksum for each row in the plurality of rows and for each column in the plurality of columns using a CRC algorithm;
appending the first checksum created for each row in the plurality of rows to the row that created the first checksum;
appending the first checksum created for each column in the plurality of columns to the column that created the first checksum;
writing each row in the plurality of rows with its appended first checksum to the memory;
writing each column in the plurality of columns with its appended first checksum to the memory.

15. The apparatus as in claim 13 wherein generating a second checksum for each row in the plurality of rows and each column in the plurality of columns comprises:
reading each row in the plurality of rows with its appended first checksum from the memory;
reading each column in the plurality of columns with its appended first checksum from the memory;
applying the CRC algorithm to each row read from the plurality of rows without its appended first checksum wherein a second checksum is created for each row from the plurality of rows;
applying the CRC algorithm to each column read from the plurality of columns without its appended first checksum wherein a second checksum is created for each column from the plurality of columns.

16. A computer comprising:
at least one CPU;
at least one block of memory;
wherein correcting soft errors occurring in the at least one block of memory comprises:
writing a block of data into the at least one block of memory wherein the block of data comprises a plurality of rows and a plurality of columns, wherein each row in the plurality of rows and each column in the plurality of columns has a first checksum appended to it;
generating a second checksum for each row in the plurality of rows and each column in the plurality of columns when each row and each column is read from the at least one block of memory;
comparing each first checksum to its corresponding second checksum for each row in the plurality of rows for a compare;
comparing each first checksum to its corresponding second checksum for each column in the plurality of columns for a compare;
wherein when one and only one column has a miscompare, a logical value of any bit at an intersection of the one and only one column that has a miscompare and any row that has a miscompare is reversed.

17. The computer as in claim 16 wherein writing a block of data into the at least one block of memory comprises:
creating the first checksum for each row in the plurality of rows and for each column in the plurality of columns using a CRC algorithm;
appending the first checksum created for each row in the plurality of rows to the row that created the first checksum;
appending the first checksum created for each column in the plurality of columns to the column that created the first checksum;
writing each row in the plurality of rows with its appended first checksum to the at least one block of memory;
writing each column in the plurality of columns with its appended first checksum to the at least one block of memory.

18. The computer as in claim 16 wherein generating a second checksum for each row in the plurality of rows and each column in the plurality of columns comprises:
reading each row in the plurality of rows with its appended first checksum from the at least one block of memory;
reading each column in the plurality of columns with its appended first checksum from the at least one block of memory;
applying the CRC algorithm to each row read from the plurality of rows without its appended first checksum wherein a second checksum is created for each row from the plurality of rows;
applying the CRC algorithm to each column read from the plurality of columns without its appended first checksum wherein a second checksum is created for each column from the plurality of columns.
